(19) United States
(12) Patent Application Publication
(10) Pub. No.: US 2026/0293642 A1
(43) Pub. Date: Sep. 24, 2026

(54) INTEGRATED CIRCUIT DEVICES INCLUDING A SELF-ALIGNED VIA-LESS CONTACT STRUCTURE AND METHODS OF FORMING THE SAME

(71) Applicant: Samsung Electronics Co., Ltd., Suwon-si (KR)

(72) Inventors: Gwang-Sik Kim, Clifton Park, NY (US); YoungGook Park, Rensselaer, NY (US); Beomjin Park, Halfmoon, NY (US); Jongmin Shin, Schenectady, NY (US); Kang-ill Seo, Springfield, VA (US)

(21) Appl. No.: 19/331,391

(22) Filed: Sep. 17, 2025

Related U.S. Application Data
(60) Provisional application No. 63/773,723, filed on Mar. 18, 2025.

(51) Int. Cl. H10W 20/42; H10W 20/00; H10W 20/41; H10W 20/43

(52) U.S. Cl. CPC H10W 20/42; H10W 20/063; H10W 20/067; H10W 20/43; H10W 20/435

(57) ABSTRACT

An integrated circuit device includes a lower metallization layer including a lower conductive line, and an upper metallization layer stacked on the lower metallization layer and including a first upper conductive line and a second upper conductive line. A thickness of a first portion of the lower conductive line that is overlapped by the second upper conductive line in a first direction is greater than a thickness of a second portion of the lower conductive line that is overlapped by the first upper conductive line in the first direction. Related devices and fabrication methods are also discussed.

### CROSS-REFERENCE TO RELATED APPLICATIONS

This application claims priority to U.S. Provisional Application Serial No. 63/773,723 entitled DEVICES INCLUDING A SELF-ALIGNED VIA-LESS CONTACT STRUCTURE AND METHODS OF FORMING THE SAME,filed in the USPTO on Mar. 18, 2025, the disclosure of which is hereby incorporated by reference herein in its entirety.

### TECHNICAL FIELD

The present disclosure generally relates to the field of electronics and, more particularly, to integrated circuit devices.

### BACKGROUND

Various back end of line (BEOL) structures of an integrated circuit device with different configurations and materials have been suggested to reduce resistance and process complexity thereof to improve the performance and the production yield of the integrated circuit device. Various interconnect schemes are part of the BEOL structures. As metal pitch continues to shrink aggressively, pattern alignment between the conductive lines and vias has become increasingly challenging. Additionally, contact resistance at the via to metal line interface is rising due to the reduction in both metal width and via size. Contact structures that address these issues with vias as devices shrink in size may be needed.

Some embodiments of the present disclosure may provide circuit devices including logic and memory elements that are formed on a substrate or wafer, using common fabrication processes. For example, a circuit device may include portions of the lower metal layer that do not have a recess and make a direct contact to an upper metal layer without the use of vias. This provides for increased contact area at the interface between the lower metal layer to upper metal layer, thereby reducing the contact resistance. Furthermore, this scheme may be beneficially used by the chemical mechanical polishing (planarization) (CMP) process since the via reveal CMP may stop at the topmost area of the lower metal layer since the via density is increased. In the integrated circuit device, a thickness of a first portion of the lower conductive line that is overlapped by the second upper conductive line in a first direction may be greater than a thickness of a second portion of the lower conductive line that is overlapped by the first upper conductive line in the first direction. The first upper conductive line may be spaced apart from the second portion the lower conductive line.

Various embodiments may be directed towards an integrated circuit device that includes a lower metallization layer comprising a lower conductive line, and an upper metallization layer stacked on the lower metallization layer and comprising a first upper conductive line and a second upper conductive line. A thickness of a first portion of the lower conductive line that is overlapped by the second upper conductive line in a first direction is greater than a thickness of a second portion of the lower conductive line that is overlapped by the first upper conductive line in the first direction.

According to some embodiments, a thickness of a first portion of the lower conductive line that is overlapped by the second upper conductive line in a first direction may be greater than a thickness of a second portion of the lower conductive line that is overlapped by the first upper conductive line in the first direction. An upper surface of the first portion of the lower conductive line may directly contact a lower surface of the second upper conductive line. A contact area between the lower conductive line and the second upper conductive line may have a width that is equal to a width of the lower conductive line. The first upper conductive line may be spaced apart from the lower conductive line.

According to some embodiments, the integrated circuit device may further include an insulating layer between the first upper conductive line and the lower conductive line. The insulating layer may be a first insulating layer, and the integrated circuit device may further include a second insulating layer that is on an upper surface of the lower conductive line and on side surfaces of the first upper conductive line and the second upper conductive line. An upper surface of the lower conductive line may be free of a recess for a via. The first portion of the lower conductive line and the second portion of the lower conductive line are collectively a monolithic conductive line. The lower conductive line in the lower metallization layer may directly contact the second upper conductive line in the upper metallization layer when the second upper conductive line overlaps only a single conductive line in the lower metallization layer. The lower conductive line may include a first lower conductive line. The integrated circuit device may further include a second lower conductive line in the lower metallization layer, a third upper conductive line in the upper metallization layer, and a conductive via that extends between the second lower conductive line and the third upper conductive line.

Various embodiments may be directed towards an integrated circuit device that includes a first region including a first lower conductive line in a lower metallization layer, a first upper conductive line in an upper metallization layer, and a second upper conductive line in the upper metallization layer, where the first lower conductive line is in direct contact with the second upper conductive line and is spaced apart from and overlaps the first upper conductive line in a first direction, and a second region comprising a second lower conductive line that overlaps a third upper conductive line that are in the upper metallization layer, where the second lower conductive line is electrically connected to the second upper conductive line by a conductive via.

According to some embodiments, a thickness of a first portion of the first lower conductive line that is in contact with the second upper conductive line in the first direction may be greater than a thickness of a second portion of the first lower conductive line that is overlapped by the first upper conductive line in the first direction. A contact area between the first lower conductive line and the second upper conductive line may have a width that is equal to a width of the lower conductive line.

According to some embodiments, the integrated circuit device may further include a first insulating layer between the first upper conductive line and the first lower conductive line, and a second insulating layer on the first lower conductive line and on side surfaces of the first upper conductive line and the second upper conductive line. A bottom surface of the second insulating layer may be coplanar with a bottom surface of the second upper conductive line.

Various embodiments may be directed towards a method of forming an integrated circuit device, which includes forming a lower metallization layer, recessing a first portion of the lower metallization layer, forming a first insulating layer on the first portion of the lower metallization layer that was recessed, forming a second insulating layer on a second portion of the lower metallization layer that was not recessed and on the first insulating layer, and forming an upper metallization layer on the first insulating layer and on a second portion of the lower metallization layer that was not recessed such that the upper metallization layer is in direct contact with the second portion of the lower metallization layer.

According to some embodiments, a thickness of the first portion of the lower metallization layer that was recessed is less than a thickness of the second portion of the lower metallization layer that was not recessed. According to some embodiments, forming the upper metallization layer may include forming a first upper conductive line that overlaps the first portion of the lower metallization layer that was recessed, and forming a second upper conductive line that overlaps the second portion of the lower metallization layer that was not recessed. According to some embodiments, the second upper conductive line may be in direct contact with the second portion of the lower metallization layer that was not recessed. According to some embodiments, a contact area between the lower metallization layer and the second upper conductive line may have a width that is equal to a width of the lower metallization layer. According to some embodiments, recessing the first portion of the lower metallization layer may include performing an etching process to remove the first portion of the lower metallization layer.

### BRIEF DESCRIPTION OF THE DRAWINGS

FIG. 1A is a schematic top or plan view of an example top-via interconnect scheme.

FIG. 1B is a schematic cross-sectional view illustrating an example top-via scheme.

FIG. 1C is a three-dimensional view of an example top-via interconnect scheme.

FIG. 2A, FIG. 2B, FIG. 2C, and FIG. 2D illustrate both a via-less scheme and a top-via scheme in an integrated circuit device, according to some embodiments of the present disclosure.

FIG. 3 illustrates a via interconnect and a via-less contact, according to some embodiments of the present disclosure.

FIG. 4A illustrates a metal top density that is evident to the CMP process of the top via interconnect scheme according to some embodiments of the present disclosure.

FIG. 4B illustrates a metal top density that is evident to the CMP process of the via-less interconnect scheme, according to some embodiments of the present disclosure.

FIG. 5, FIG. 6, and FIG. 7 are flowcharts of operations of a method of forming an integrated circuit device, according to some embodiments of the present disclosure.

FIG. 8A, FIG. 8B, FIG. 8C, FIG. 8D, FIG. 8E, FIG. 8F, FIG. 8G, and FIG. 8H, illustrate a method of forming an integrated circuit device according to various embodiments of the present disclosure.

Example embodiments are described herein with reference to the accompanying drawings, which may include cross-section illustrations that are schematic illustrations of idealized embodiments (and intermediate structures). The sizes and relative sizes of layers and regions may be exaggerated for clarity. Additionally, variations from the shapes of the illustrations as a result, for example, of manufacturing techniques and/or tolerances, are to be expected. The same reference numerals may be used to refer to the same or similar elements in various embodiments, where reference numerals followed by a letter (a, b, c, etc.) or one or more prime symbols (‘) may refer to specific instances or variations of the same or similar elements.

A top-via interconnect scheme may be part of a back end of line (BEOL) patterning scheme of an integrated circuit device (e.g., a semiconductor device) manufacturing method. The top-via interconnect scheme may improve the efficiency of the integrated circuit device manufacturing method. The top-via interconnect scheme may include a metal line recess process to form top-vias and lower metal lines by blocking (e.g., masking) some metal lines and recessing the other metal lines. In some embodiments, the size of the top-via, which may be less than a size of a via formed during a damascene process, may be formed from a lower metal line such that it does not exceed a width of the lower metal line. As metal pitch continues to shrink, issues in manufacturing devices occur, such as pattern alignment between conductive lines and vias, increased contact resistance at the via to conductive line interface due to the reduction in both line width and via size. These challenges are particularly pronounced in the top-via scheme, where the via must be smaller than in the conventional damascene scheme, as it is formed from the lower metal line and cannot exceed the width of the lower metal. Various embodiments described herein introduce a self-aligned contact structure between the upper and lower conductive lines at specific points, reducing misalignment issues, reducing contact resistance, and potentially improving CMP process margin.

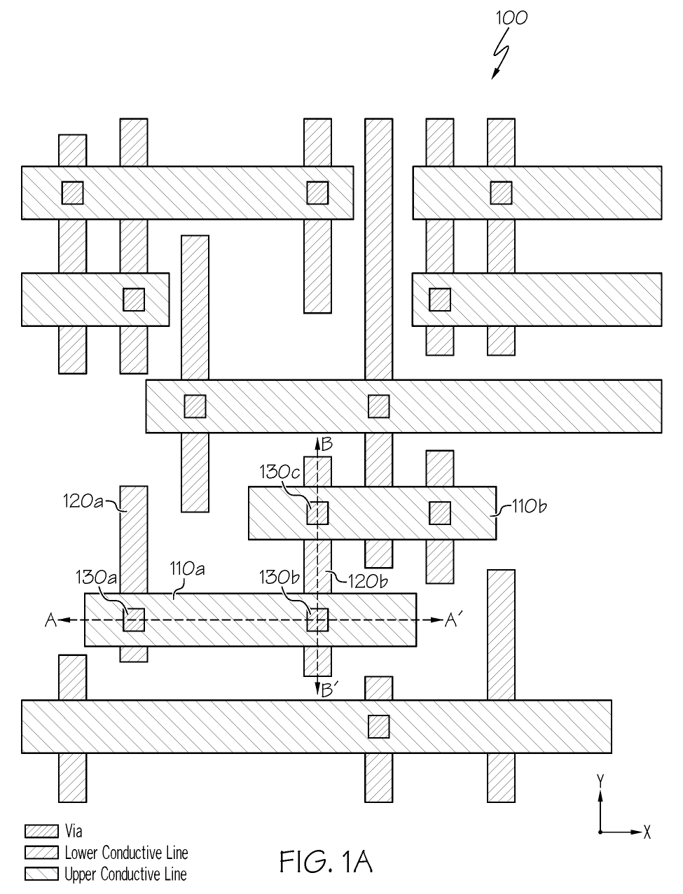

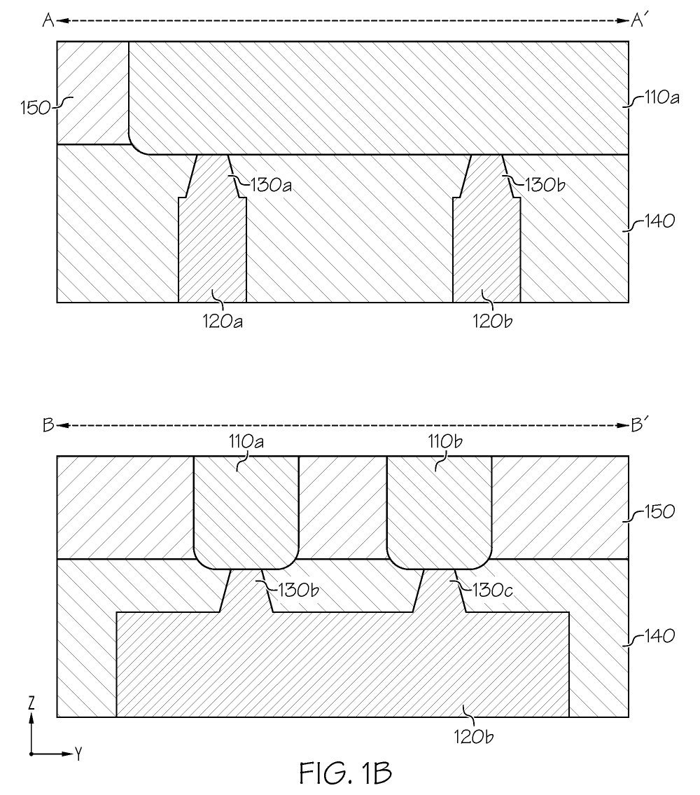

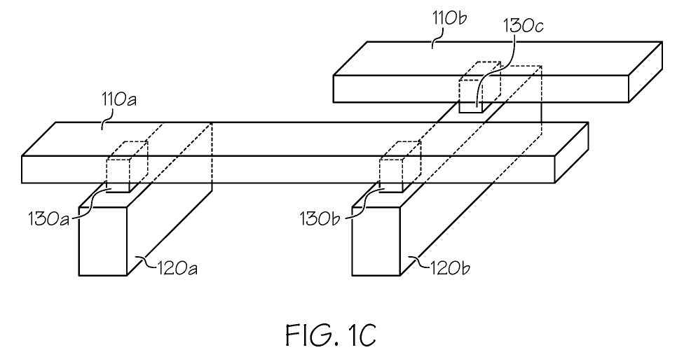

FIG. 1A, FIG. 1B, and FIG. 1C illustrate a top-via interconnect scheme of an integrated circuit device. FIG. 1A is a schematic top view or plan view of the top-via interconnect scheme. FIG. 1B is a schematic cross-sectional view illustrating example via schemes. FIG. 1C is a three-dimensional view of a top-via interconnect scheme. Referring to FIGS. 1A and 1B, integrated circuit device 100 may include a via 130a that is formed from the lower metal line 120a to make a connection to the upper metal line 110a. The width of the via 130a may be less than that a width of the lower metal line 120a due to its formation process, which may include dry etching. Due to the relatively smaller size of the via 130a, it may be difficult to pattern the upper metal line 110a to make a reliable connection to the via 130a. Similarly, via 130b may connect lower metal line 120b to upper metal line 110a, and via 130c may connect lower metal line 120b to upper metal line 110b.

Referring to FIG. 1B, at cross-section A-A’ of FIG. 1A, lower metal line 120a may include a recess for via 130a to connect (e.g., electrically and/or physically) to upper metal line 110a. Similarly, lower metal line 120b may include two recesses for via 130b and 130c to connect to upper metal lines 110a and 110b, respectively.

Referring to FIG. 1C, the three-dimensional view illustrates that upper metal line 110a overlaps lower metal lines 120a and 120b. Upper metal line 110b overlaps lower metal line 120b. Via 130a connects upper metal line 110a and lower metal line 120a. Vias 130b and 130c respectively connect upper metal lines 110a and 110b to lower metal line 120b.

However, according to the embodiments of FIGS. 1A, 1B, and 1C, it may be difficult to align the conductive lines and the vias during the metal line recess process as the metal pitch of the integrated circuit device decreases. Moreover, the contact resistance at an interface between the top-via and the metal lines may increase as the metal width decreases and/or the size of the top-via decreases.

Some embodiments of the present inventive concepts arise from the recognition that an integrated circuit device may include self-aligned, via-less contact structures that are selectively positioned between the upper conductive lines (also referred to as Mₓ₊₁) and the lower conductive lines (also referred to as Mₓ) to thereby reduce misalignment issues, reduce contact resistance, and/or improve a chemical mechanical polishing (CMP) process margin.

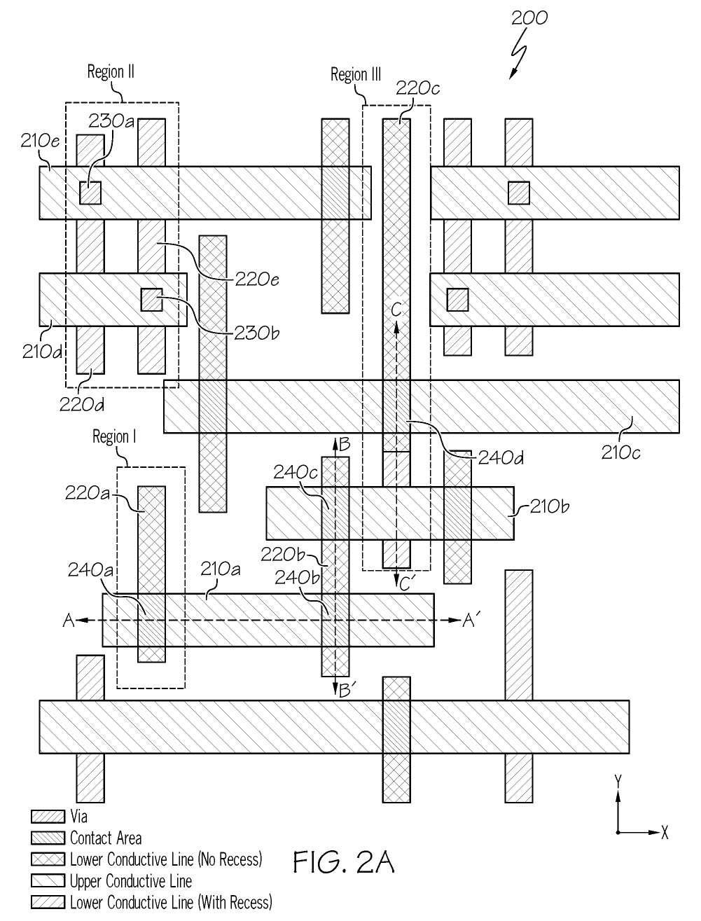

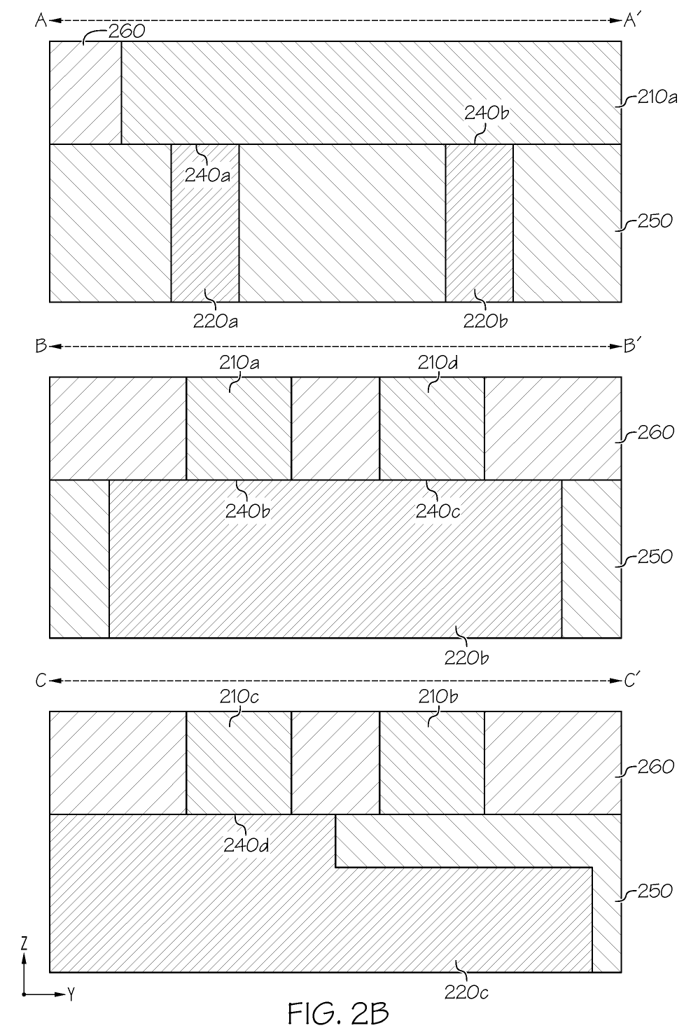

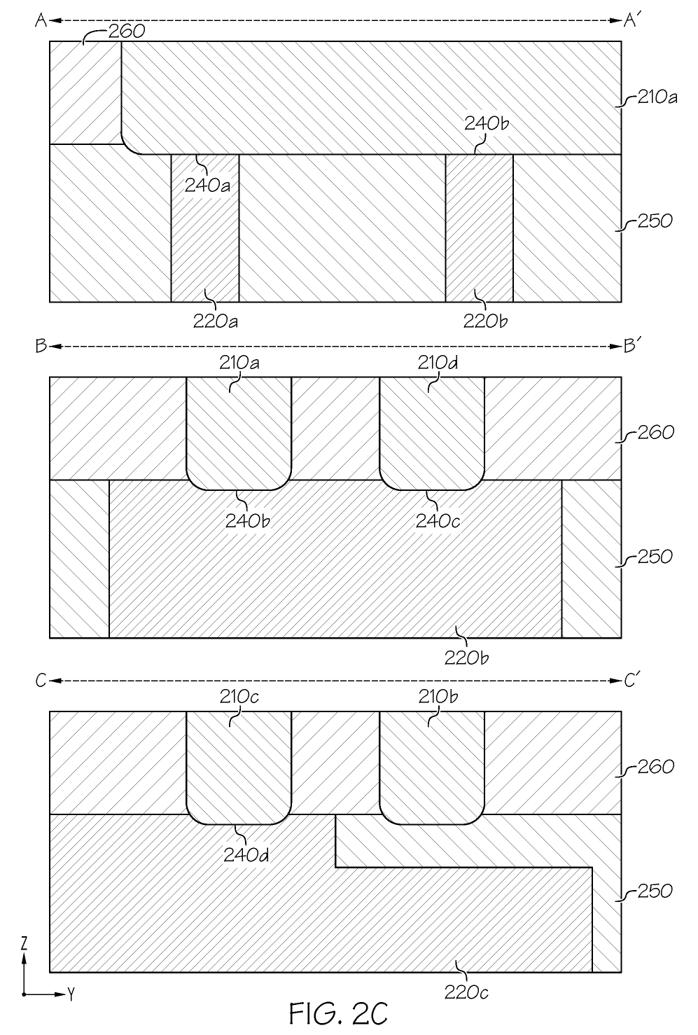

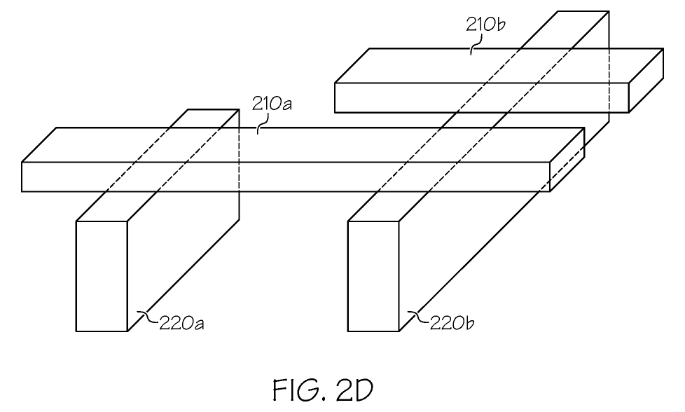

FIG. 2A, FIG. 2B, and FIG. 2C illustrate both a via-less scheme and a top-via scheme in an integrated circuit device. FIG. 2A is a schematic top view or plan view that includes the via-less interconnect scheme. FIG. 2B and FIG. 2C are schematic cross-sectional views illustrating example via-less and via schemes in an integrated circuit device. FIG. 2D is a three-dimensional view of the via-less interconnect scheme.

Referring to FIG. 2A, Region I includes a via-less contact structure, Region II includes a top-via contact structure, and Region III includes a case where a first portion of the lower metal line may not have a recess structure while a second portion may have a recess structure.

Referring to FIG. 2A and FIG. 2B, in Region I, the lower conductive line 220a contacts the upper conductive line 210a at contact area 240a. In the x-direction, the width of the contact area 240a is equal to the width of the lower conductive line 220a. In the y-direction, the width of the contact area 240a is equal to the width of the upper conductive line 210a. Lower conductive line 220a does not include a recess since a via is not needed since the via-less scheme is utilized in Region I.

In Region II, via 230a connects lower conductive line 220d to upper conductive line 210e. Via 230b connects lower conductive line 220e to upper conductive line 210d. Both lower conductive lines 220d and 220e include recesses for vias.

In Region III, a first portion of lower conductive line 220c does not have a recess since direct contact is made between the lower conductive line 220c and the upper conductive line 210c at contact area 240d. For example, contact area 240d may have a width <9 nm. A recess in a second portion of lower conductive line 220c is present in the area of overlap between lower conductive line 220c and upper conductive line 210b. The recess ensures that lower conductive line 220c and upper conductive line 210b are electrically isolated from one another. In some embodiments, the characteristics of the first and second portions of the lower conductive line 220c may be based on the margin and/or distance between adjacent conductive lines (e.g., the horizontal distance between the upper conductive lines) or a horizontal distance between the first and second portions of the lower conductive line 220c may be selected such that the margin therebetween is sufficient to prevent electrical shorts.

Referring to FIG. 2B, at cross-section A-A’ of FIG. 2A, upper conductive line 210a directly contacts lower conductive line 220a at contact area 240a and directly contacts lower conductive line 220b at contact area 240b. For example, contact area 240b may have a width <9 nm. An insulating layer 250, such as a low-k dielectric material, may be between lower conductive lines 220a and 220b and/or may be in the layer of the lower conductive lines of the integrated circuit device 200. The low-k dielectric material may have a dielectric constant, k, that is, for example, less than a dielectric constant of silicon dioxide. An insulating layer 260, such as a dielectric material, may be in the layer of the upper conductive lines. The dielectric constant k of the insulating layer 250, which is a measure of a material's ability to store electrical energy in an electric field, may be less than the dielectric constant of the insulating layer 260. Referring to FIG. 2B, at cross-section B-B’ of FIG. 2A, upper conductive line 210a and upper conductive line 210b both directly contact lower conductive line 220b at contact area 240b and contact area 240c, respectively.

Still referring to FIG. 2B, at cross-section C-C’ of FIG. 2A, upper conductive line 210c directly contacts lower conductive line 220c at contact area 240d. As shown in the cross-sectional view, a via-less direct contact is made between the upper conductive line 210c and the lower conductive line 220c such that a recess is not present in the lower conductive line 220c in this portion of the lower conductive line 220c. In other words, lower conductive line 220c may not be recessed at specific portions to define vias protruding therefrom, thereby enabling direct contact between a lower conductive line in layer Mₓ and an upper conductive line in layer Mₓ₊₁, without vias therebetween. Upper conductive line 210b overlaps lower conductive line 220c in the z-direction. However, lower conductive line 220c is recessed in the portion that overlaps upper conductive line 210b such that lower conductive line 220c is electrically isolated from upper conductive line 210b. Insulating layer 250, such as a low-k dielectric material, may be in the space between lower conductive line 220c and upper conductive line 210b. An insulating layer 260 may be on insulating layer 250 and may be on sidewalls of upper conductive lines 210a, 210b, 210c, and/or 210d. Insulating layer 250 and insulating layer 260 may be a same material with different dielectric constants or may be different insulating materials. Insulating layer 250 and insulating layer 260 may be formed by different processes.

Referring to FIG. 2C, according to some embodiments, the upper conductive lines 210a, 210b, 210c, or 210d, may extend into the lower conductive lines 220a, 220b, or 220c. Other features according to FIG. 2C may be similar to those described with respect to FIG. 2B, and thus will not be repeated for brevity.

Referring to FIG. 2D, upper conductive line 210a directly contacts both lower conductive line 220a and lower conductive line 220b, without a via therebetween. Upper conductive line 210b directly contacts lower conductive line 220b, without a via therebetween. Therefore, lower conductive lines 220a and 220b do not include recesses for vias, simplifying the manufacturing process in this portion of the integrated circuit device.

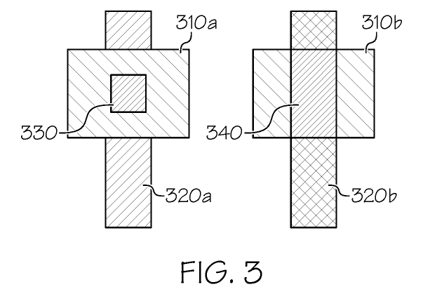

FIG. 3 illustrates a via interconnect and a via-less contact, according to various embodiments described herein. Referring to FIG. 3, lower conductive line 320a is electrically connected to upper conductive line 310a by a via 330. Lower conductive line 320b directly contacts upper conductive line 310b at contact area 340. The contact area 340 is greater than the cross-sectional area of via 330, thereby reducing the contact resistance between the upper and lower conductive lines. Reducing the contact resistance may provide the benefit of better electrical performance of the integrated circuit device.

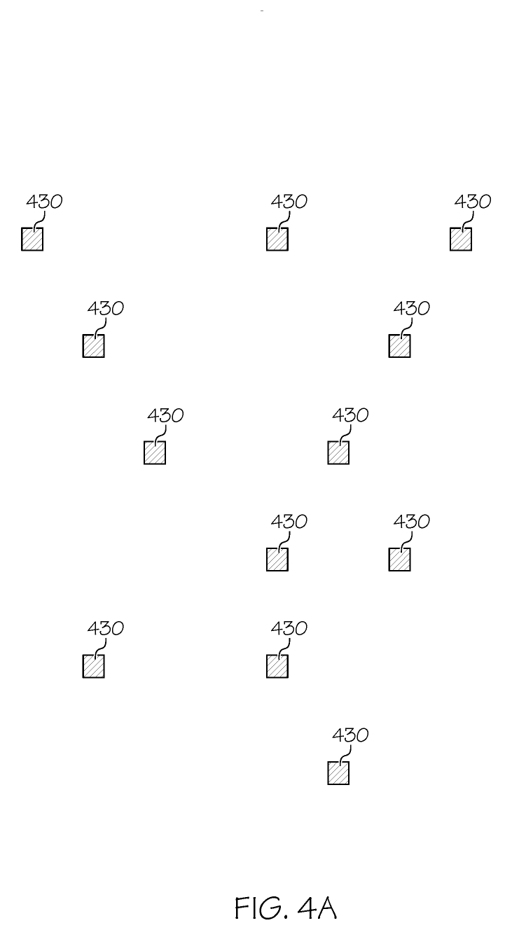

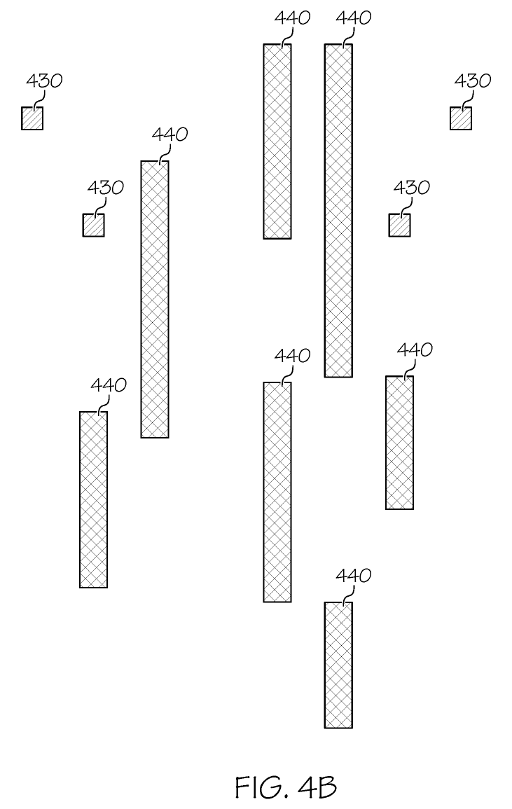

FIG. 4A illustrates a metal top density that is evident to the CMP process of the top via interconnect scheme, according to some embodiments. FIG. 4B illustrates a metal top density that is evident to the CMP process of the via-less interconnect scheme, according to some embodiments. Referring to FIG. 4A, the various vias 430 of the top-via interconnect scheme of FIG. 1A, FIG. 1B, and/or FIG. 1C are shown. Referring to FIG. 4B, the vias 430 and the contact areas 440 of the via-less interconnect scheme for some electrical connections of FIG. 2A, FIG. 2B, FIG. 2C, and/or FIG. 2D are shown. The integrated circuit device may have improved compatibility with CMP processes, as the via reveal during the CMP process may stop at the lower conductive lines as the via density (e.g., a via density at an uppermost area) increases. In other words, as shown in FIG. 4B, the via-less interconnect scheme provides larger conductive areas that are easier to sense during the CMP process, thus reducing the speed of the CMP process.

According to various embodiments described herein, and as shown above in example embodiments related to FIGS. 2A, 2B, 2C, 2D, 3, and 4 the integrated circuit device selectively includes direct contact between the upper conductive lines and lower conductive lines at various locations thereof. Accordingly, the integrated circuit device improves the alignment between the upper conductive lines and the conductive lines even when the metal pitch of the integrated circuit device decreases. Furthermore, the integrated circuit device has reduced contact resistance between the upper conductive lines and the lower conductive lines by enlarging the contact area therebetween. Additionally, the larger contact areas between layers improve the CMP process.

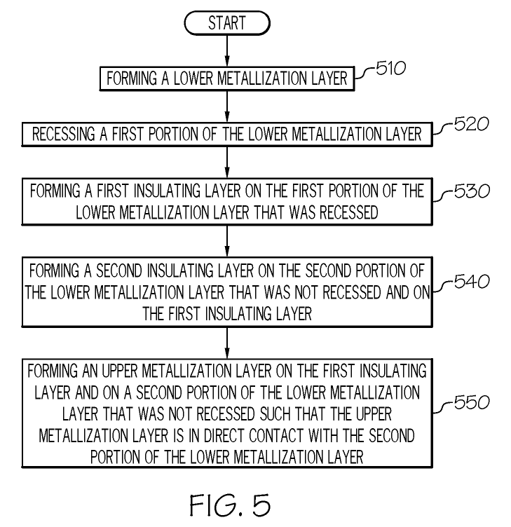

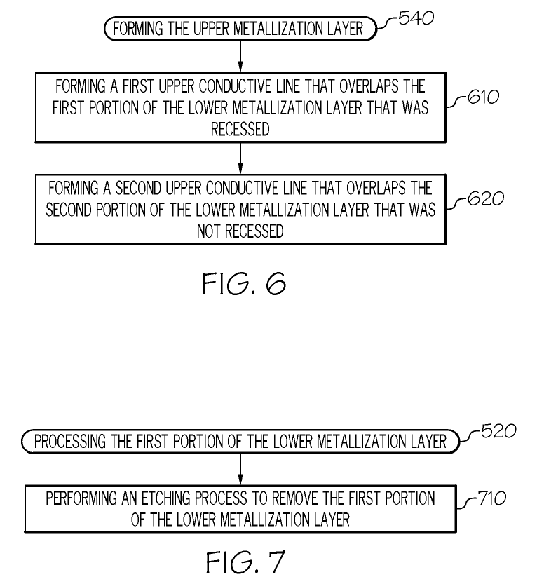

FIG. 5, FIG. 6, and FIG. 7 are flowcharts of operations of a method of forming an integrated circuit device, according to some embodiments of the present disclosure. Referring to FIG. 5, the method of forming an integrated circuit device may include, forming a lower metallization layer, at block 510. The method may include recessing a first portion of the lower metallization layer, at block 520. The method may include forming a first insulating layer on the first portion of the lower metallization layer that was recessed, at block 530. The method may include forming a second insulating layer on a second portion of the lower metallization layer that was not recessed and on the first insulating layer, at block 540. The method may include forming an upper metallization layer on the first insulating layer and on a second portion of the lower metallization layer that was not recessed such that the upper metallization layer is in direct contact with the second portion of the lower metallization layer, at block 550. A thickness of the first portion of the lower metallization layer that was recessed may be less than a thickness of the second portion of the lower metallization layer that was not recessed.

Referring FIG. 6, according to some embodiments, forming the upper metallization layer, at block 540, may include forming a first upper conductive line that overlaps the first portion of the lower metallization layer that was recessed, at block 610, and forming a second upper conductive line that overlaps the second portion of the lower metallization layer that was not recessed, at block 620. According to some embodiments, the second upper conductive line may be in direct contact with the second portion of the lower metallization layer that was not recessed. According to some embodiments, a contact area between the lower metallization layer and the second upper conductive line may have a width that is equal to a width of the lower metallization layer.

Referring FIG. 7, according to some embodiments, recessing the first portion of the lower metallization layer, at block 520, may include performing an etching process to remove the first portion of the lower metallization layer, at block 710.

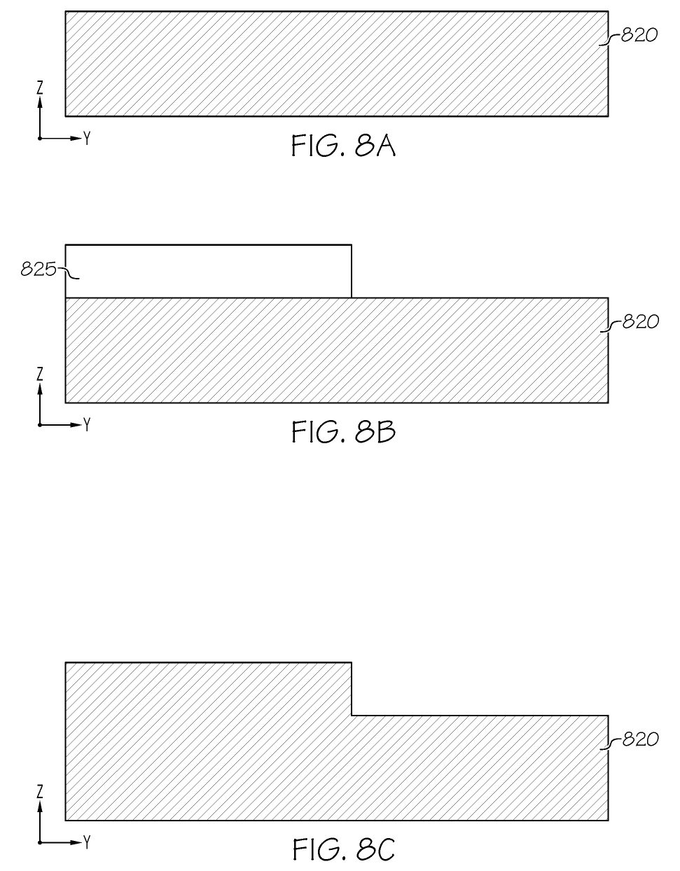

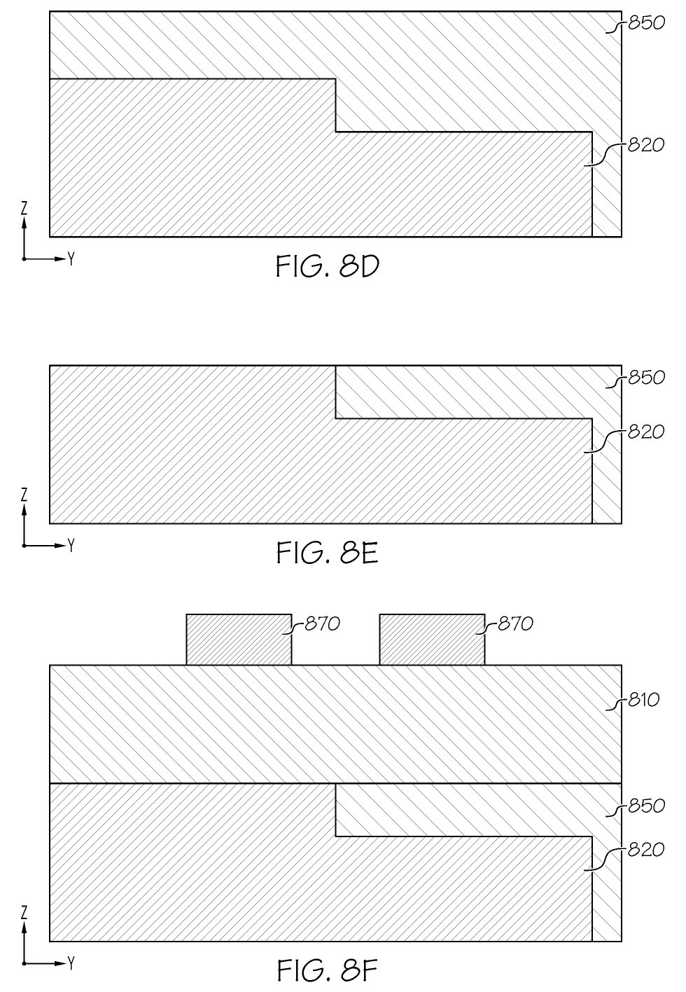

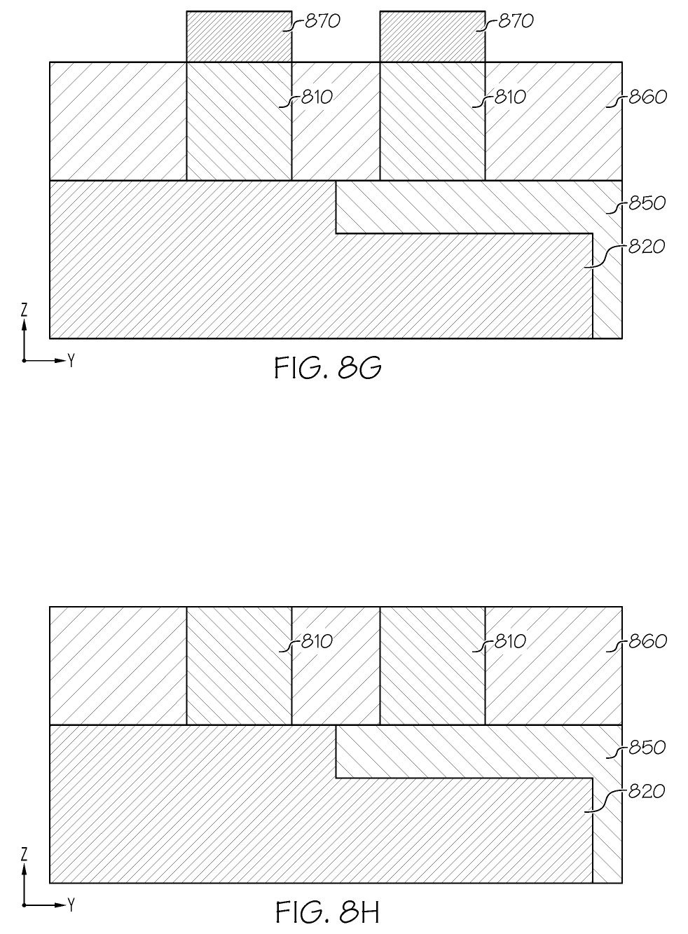

FIG. 8A, FIG. 8B, FIG. 8C, FIG. 8D, FIG. 8E, FIG. 8F, FIG. 8G, and FIG. 8H, illustrate a method of forming an integrated circuit device according to various embodiments described herein. FIG. 8A is a cross-sectional view of an intermediate process to provide a lower metallization layer. Referring to FIG. 8A, a lower metallization layer 820 may be formed on a substrate. The lower metallization layer 820 may be formed of one or more conductive materials including, for example, copper (Cu), aluminum (Al), cobalt (Co), tungsten (W), titanium (Ti), tantalum (Ta) or their combination.

FIG. 8B is a cross-sectional view of an intermediate process to form a mask pattern. Referring to FIG. 8B, a mask pattern 825 may be formed on the lower metallization layer 820. The mask pattern 825 overlaps a portion of the lower metallization layer 820 and is used in a subsequent operation during an etching process. The mask pattern 825 prevents etching of a portion of the lower metallization layer 820.

FIG. 8C is a cross-sectional view of an intermediate process to form a recess. Referring to FIG. 8C, an etching process may be performed to etch a first portion of the lower metallization layer 820 to form a recess. Specifically, during the etching operation, the portion of the lower metallization layer 820 that is overlapped by the mask pattern 825 is not etched, whereas the uncovered portion of lower metallization layer 820 is etched to form a recess.

FIG. 8D is a cross-sectional view of an intermediate process to include an insulating layer in the recess. Referring to FIG. 8D, a first insulating layer 850 may be formed in the recess where the first portion of the lower metallization layer was recessed, and on the second portion of the lower metallization layer 820 that was not recessed.

FIG. 8E is a cross-sectional view of an intermediate process to perform a CMP process. Referring to FIG. 8E, a CMP process may be performed to remove portions of the first insulating layer 850. The CMP process may stop at the lower metallization layer 820 as the density (e.g., a density at an uppermost area of the lower metallization layer 820) increases. In other words, as shown in FIG. 8E, the via-less interconnect scheme provides a larger conductive area (i.e., the second portion of the lower metallization layer 820) that is easier to sense or detect during the CMP process, thus reducing the speed of the CMP process. Thus, the CMP process may remove a portion of the first insulating layer 850 that is on the surface of the second portion of the lower metallization layer 820 that was not recessed. As a result, a topmost surface of the first insulating layer 850 may be coplanar with a topmost surface of the lower metallization layer 820. After the CMP process, a top portion of the lower metallization layer 820 is exposed, whereas the first insulating layer 850 is on the recessed portioned of the lower metallization layer 820.

FIG. 8F is a cross-sectional view of an intermediate process to add an upper metallization layer 810. Referring to FIG. 8F, an upper metallization layer 810 is provided on the exposed portion of the lower metallization layer 820 and the first insulating layer 850. As an example, the upper metallization layer may include copper (Cu), aluminum (Al), cobalt (Co), ruthenium (Ru), molybdenum (Mo), tungsten (W), titanium (Ti), tantalum (Ta), or other conductive materials. Furthermore, mask patterns 870 may be provided on the top surface of the upper metallization layer 810.

FIG. 8G is a cross-sectional view of an intermediate process to provide a second insulating layer 860 on the device. Referring to FIG. 8G, an etching process may be performed to remove portions of the upper metallization layer 810 that are not masked. A second insulating layer 860 may be provided in the resulting recesses between portions of the upper metallization layer 810 that was not etched due to the masking layer 870. The dielectric constant k of the first insulating layer 850 may be less than the dielectric constant of the second insulating layer 860.

FIG. 8H is a cross-sectional view of a process to remove the masking layer 870 of FIG. 8G. Referring to FIG. 8H, the masking layer 870 is removed. The top surfaces of the upper metallization layer 810 are exposed. The remaining portions of the upper metallization layer 810 form the upper conductive lines 210a, 210b, 210c, or 210d illustrated in FIG. 2B. These processes described herein thus provide an integrated circuit device that does not include vias, but has direct contact (i.e., via-less contact) between some portions of the upper metallization layer 810 and the lower metallization layer 820. The upper metallization layer 810 may be spaced apart from the recessed portion of the lower metallization layer 820 with the first insulating layer 850 therebetween.

According to some embodiments, instead of the process described with respect to FIG. 8F and FIG. 8G, a second insulating layer 860 may be provided on the top surface of the exposed lower metallization layer 820 of FIG. 8F and the first insulating layer 850. A mask pattern may be placed on the second insulating layer 860. An etching process may be performed to etched recesses in the second insulating layer 860. An upper metallization layer 810 may be provided in the recesses in the second insulation layer 860. The upper metallization layer 810 may be in direct contact with the lower metallization layer 820 at the second portion at the top surface of the lower metallization layer 820. The upper metallization layer 810 may be spaced apart from the recessed portion of the lower metallization layer 820 with the first insulating layer 850 therebetween.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein. For example, as noted herein, an “insulating” layer or liner may include dielectric materials (which may be polarizable by an applied electric field) that have electrically insulating properties.

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure.

The terminology used herein is for the purpose of describing particular embodiments only and is not intended to be limiting of embodiments. The singular forms "a," "an," and "the" are intended to include the plural forms as well, unless the context clearly indicates otherwise. The terms "comprises," "comprising," "includes" and/or "including" specify the presence of stated features, steps, operations, elements and/or components, but do not preclude the presence or addition of one or more other features, steps, operations, elements, components and/or groups thereof.

It will be understood that, although the terms “first,” “second,” etc. are used throughout this specification to describe various elements, these elements should not be limited by these terms. These terms are only used to distinguish one element from another. For example, a first element could be termed a second element, and, similarly, a second element could be termed a first element, without departing from the scope of the present disclosure. The term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Elements that are “connected” as described herein may be physically and/or electrically connected.

Spatially relative terms such as “below” or “above” or “upper” or “lower” or “top” or “bottom” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Many different forms and embodiments are possible without deviating from the teachings of this disclosure. Accordingly, the disclosure should not be construed as limited to the example embodiments set forth herein. As such, it will be understood by those of ordinary skill in the art that various changes in form and details may be made therein without departing from the spirit and scope as defined herein.

Embodiments of the invention are also described with reference to a fabrication operations and flowchart diagrams. It will be appreciated that the steps shown in the fabrication operations and flowchart diagrams need not be performed in the order shown.

It should be noted that in some alternate implementations, the functions/acts noted in flowchart blocks herein may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of the present inventive concept.

The above-disclosed subject matter is to be considered illustrative, and not restrictive, and the appended claims are intended to cover all such modifications, enhancements, and other embodiments, which fall within the scope of the disclosure. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a lower metallization layer comprising a lower conductive line; and
an upper metallization layer stacked on the lower metallization layer and comprising a first upper conductive line and a second upper conductive line,
wherein a thickness of a first portion of the lower conductive line that is overlapped by the second upper conductive line in a first direction is greater than a thickness of a second portion of the lower conductive line that is overlapped by the first upper conductive line in the first direction.

2. The integrated circuit device of claim 1, wherein an upper surface of the first portion of the lower conductive line directly contacts a lower surface of the second upper conductive line.

3. The integrated circuit device of claim 1, wherein a contact area between the lower conductive line and the second upper conductive line has a width that is equal to a width of the lower conductive line.

4. The integrated circuit device of claim 1, wherein the first upper conductive line is spaced apart from the lower conductive line.

5. The integrated circuit device of claim 4, further comprising:
an insulating layer between the first upper conductive line and the lower conductive line.

6. The integrated circuit device of claim 5, wherein the insulating layer comprises a first insulating layer, the integrated circuit device further comprising:
a second insulating layer that is on an upper surface of the lower conductive line and on side surfaces of the first upper conductive line and the second upper conductive line.

7. The integrated circuit device of claim 1, wherein an upper surface of the lower conductive line is free of a recess for a via.

8. The integrated circuit device of claim 1, wherein the first portion of the lower conductive line and the second portion of the lower conductive line are collectively a monolithic conductive line.

9. The integrated circuit device of claim 1, wherein the lower conductive line in the lower metallization layer directly contacts the second upper conductive line in the upper metallization layer when the second upper conductive line overlaps only a single conductive line in the lower metallization layer.

10. The integrated circuit device of claim 1, wherein the lower conductive line comprises a first lower conductive line , the integrated circuit device further comprising:
a second lower conductive line in the lower metallization layer;
a third upper conductive line in the upper metallization layer; and
a conductive via that extends between the second lower conductive line and the third upper conductive line.

11. An integrated circuit device comprising:
a first region comprising a first lower conductive line in a lower metallization layer, a first upper conductive line in an upper metallization layer, and a second upper conductive line in the upper metallization layer, wherein the first lower conductive line is in direct contact with the second upper conductive line and is spaced apart from and overlaps the first upper conductive line in a first direction; and
a second region comprising a second lower conductive line that overlaps a third upper conductive line that are in the upper metallization layer, wherein the second lower conductive line is electrically connected to the second upper conductive line by a conductive via.

12. The integrated circuit device of claim 11, wherein a thickness of a first portion of the first lower conductive line that is in contact with the second upper conductive line in the first direction is greater than a thickness of a second portion of the first lower conductive line that is overlapped by the first upper conductive line in the first direction.

13. The integrated circuit device of claim 11, wherein a contact area between the first lower conductive line and the second upper conductive line has a width that is equal to a width of the lower conductive line.

14. The integrated circuit device of claim 11, further comprising:
a first insulating layer between the first upper conductive line and the first lower conductive line ; and
a second insulating layer on the first lower conductive line and on side surfaces of the first upper conductive line and the second upper conductive line.

15. The integrated circuit device of claim 14, wherein a bottom surface of the second insulating layer is coplanar with a bottom surface of the second upper conductive line.

16. A method of forming an integrated circuit device, the method comprising:
forming a lower metallization layer;
recessing a first portion of the lower metallization layer;
forming a first insulating layer on the first portion of the lower metallization layer that was recessed;
forming a second insulating layer on a second portion of the lower metallization layer that was not recessed and on the first insulating layer; and
forming an upper metallization layer on the first insulating layer and on a second portion of the lower metallization layer that was not recessed such that the upper metallization layer is in direct contact with the second portion of the lower metallization layer,
wherein a thickness of the first portion of the lower metallization layer that was recessed is less than a thickness of the second portion of the lower metallization layer that was not recessed.

17. The method of forming the integrated circuit device of claim 16, wherein forming the upper metallization layer comprises:
forming a first upper conductive line that overlaps the first portion of the lower metallization layer that was recessed; and
forming a second upper conductive line that overlaps the second portion of the lower metallization layer that was not recessed.

18. The method of forming the integrated circuit device of claim 17, wherein the second upper conductive line is in direct contact with the second portion of the lower metallization layer that was not recessed.

19. The method of forming the integrated circuit device of claim 17, wherein a contact area between the lower metallization layer and the second upper conductive line has a width that is equal to a width of the lower metallization layer.

20. The method of forming the integrated circuit device of claim 17, wherein the recessing the first portion of the lower metallization layer comprises:
performing an etching process to remove the first portion of the lower metallization layer.
